(19) United States
(12) Patent Application Publication
(10) Pub. No.: US 2007/0132593 A1
(43) Pub. Date: Jun. 14, 2007

(54) RFID tag

(75) Inventor: Midori Yamazaki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/391,287

(22) Filed: Mar. 29, 2006

(30) Foreign Application Priority Data
Dec. 14, 2005 (JP) 2005-360851

(51) Int. Cl. G08B 13/14; G06K 19/06; H01L 23/28

(52) U.S. Cl. 340/572.8; 235/492; 257/787

(57) ABSTRACT

A Radio Frequency Identification (RFID) tag includes an integrated circuit (IC) chip and an antenna. The IC chip is enclosed inside a coating of endothermic material. The endothermic material includes silicon resin or ceramic resin or both.

### BACKGROUND OF THE INVENTION

1. Field of the Invention

The present invention relates to a Radio Frequency Identification (RFID) tag.

2. Description of the Related Art

Various applications of RFID tags are being considered, such as identifying and managing people and objects, and as a basic technology for promoting automation in the society. Communication is performed through electric waves and electromagnetic waves between an RFID tag (also referred to as an IC tag) including an IC chip for storing information and an antenna for performing wireless communication, and a reader/writer that reads information inside the RFID tag in a noncontact manner.

One application is to attach an RFID tag to a product instead of a conventional barcode. The RFID tag stores identification information on the product. RFID tags are more advantageous than barcodes in that RFID tags can store a large amount of information, a plurality of RFID tags can be simultaneously read by a reader/writer, and information in an RFID tag can be overwritten. Thus, RFID tags are expected to promote efficiency in commercial distribution.

Japanese Patent Application Laid Open Nos. 2001-317741 and 2005-242629 disclose a technology for attaching an RFID tag to a container for containing cooking ingredients, and storing a preparation method for the ingredients in the container. Specifically, a microwave oven reads the preparation method stored in the RFID tag attached to the container, and controls cooking time based on the information read.

However, when a container to which an RFID tag has been attached is heated in a microwave oven, the RFID tag is destroyed by strong electromagnetic waves generated by the microwave oven and components of the RFID tag scatter and damage the microwave oven. When a typical RFID tag is heated in a microwave oven, the RFID tag is heated to a high temperature just in a few seconds. Sometimes the IC chip in the hot RFID tag explodes, and metal components of the RFID tag scatter inside the microwave oven.

RFID tags are becoming increasingly popular. It is expected that RFID tags will be attached to a wide variety of food products in the future. Accordingly, there will be higher chance that an RFID tag attached to a food product is heated by a microwave oven. Thus, there is a need to develop an RFID tag that is not destroyed when heated in a microwave oven.

### SUMMARY OF THE INVENTION

It is an object of the present invention to at least solve the problems in the conventional technology.

According to an aspect of the present invention, a radio frequency identification (RFID) tag includes an integrated circuit (IC) chip configured to store therein information; an antenna configured to perform wireless communication with outside; and a coating of endothermic material configured to enclose the IC chip.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic of an RFID tag according to an embodiment of the present invention;

FIG. 2 is an enlarged view of an IC chip shown in FIG. 1; and

FIG. 3 is a schematic of a conventional RFID tag 100.

### DETAILED DESCRIPTION OF THE PREFERRED EMBODIMENTS

Exemplary embodiments of the present invention will be described below with reference to accompanying drawings. The present invention is not limited to these embodiments.

FIG. 3 is a schematic of a conventional RFID tag 100. The RFID tag 100 includes an IC chip 110 and an antenna 120. The IC chip 110 is a semiconductor circuit including a memory for storing information and a control circuit for controlling communication between a reader/writer. The antenna 120 is provided for performing wireless communication between the reader/writer.

When the RFID tag 100 is heated in a microwave oven, the antenna 120 resonates with an electromagnetic wave of 2.45 GHz generated by magnetron incorporated in the microwave oven, and generates heat and causes electrical discharge. The heat and discharge is transferred to the IC chip 110 and destroys the IC chip 110.

The IC chip 110 is destroyed only a few seconds after the heating starts, which is shorter than time required for cooking food in the microwave oven. Accordingly, when food attached with a conventional RFID tag is heated in the microwave oven, the RFID tag is destroyed before cooking is completed, and therefore, the microwave oven will be damaged.

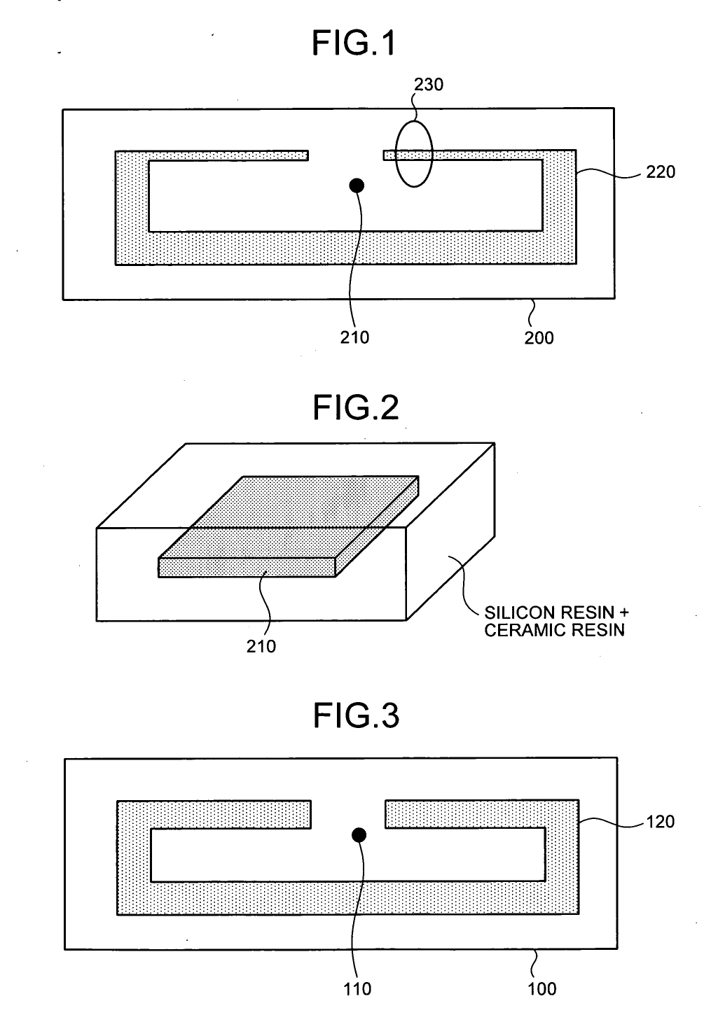

FIG. 1 is a schematic of an RFID tag 200 according to an embodiment of the present invention. The RFID tag 200 includes an IC chip 210, an antenna 220, and a low-pass filter 230.

The IC chip 210 is a semiconductor circuit including a memory for storing information and a control circuit for controlling communication between a reader/writer. The IC chip 210 has the same function as the IC chip 110; however, the IC chip 210 is embedded in endothermic material as shown in FIG. 2. This improves heat resistance, so that the IC chip 210 is hard to destroy.

Silicon resin, ceramic resin, or a mixture of these resins is effective as the endothermic material. Heat resistance can be further improved by adding silica gel to either one of the resins or the mixture.

The antenna 220 is provided for performing wireless communication between the reader/writer. The antenna 220 has the same function as the antenna 120; however, the antenna 220 is shaped so that one part is thinner than another part. When the RFID tag 200 is heated in a microwave oven, the thinner part becomes disconnected due to heat and electric discharge, so that heat is prevented from being transferred to the IC chip 210. The same effect can be obtained by disconnecting a part of the antenna 220 beforehand.

The low-pass filter 230 blocks an electromagnetic wave of 2.45 GHz. By inserting the low-pass filter 230 midway in the antenna 220, the antenna 220 is prevented from resonating with electromagnetic waves generated by the magnetron. The low-pass filter 230 can be realized by a ceramic material of approximately a 1 mm angle.

The embodiment prevents resonation by inserting a low-pass filter in an antenna, prevents heat from being transferred to an IC chip by shaping the antenna to be easily disconnected, and improves heat resistance by embedding the IC chip in endothermic material. This configuration realizes an RFID tag that is not destroyed even when heated in a microwave oven.

According to an aspect of the present invention, heat resistance of an IC chip is improved.

Furthermore, heat is prevented from being transferred to the IC chip.

Moreover, resonance caused by electromagnetic waves generated by magnetron is prevented.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A Radio Frequency Identification (RFID) tag comprising:
an integrated circuit (IC) chip configured to store therein information;
an antenna configured to perform wireless communication with outside; and
a coating of endothermic material configured to enclose the IC chip.

2. The RFID tag according to claim 1, wherein the endothermic material includes silicon resin.

3. The RFID tag according to claim 2, wherein the endothermic material includes silica gel.

4. The RFID tag according to claim 1, wherein the endothermic material includes ceramic resin.

5. The RFID tag according to claim 4, wherein the endothermic material includes silica gel.

6. The RFID tag according to claim 1, wherein the endothermic material includes a mixture of silicon resin and ceramic resin.

7. The RFID tag according to claim 6, wherein the endothermic material includes silica gel.

8. The RFID tag according to claim 1, wherein
the antenna includes a first part and a second part, and
the first part is thinner than the second part.

9. The RFID tag according to claim 1, further comprising
a low-pass filter that blocks an electromagnetic wave of a frequency band generated by magnetron.
